(19) United States
(12) Patent Application Publication
(10) Pub. No.: US 2024/0201480 A1
(43) Pub. Date: Jun. 20, 2024

(54) Display Device

(71) Applicant: LG Display Co., Ltd., Seoul (KR)

(72) Inventors: SeYeoul Kwon, Goyang-si (KR); ChangSoo Kim, Paju-si (KR); JeongOk Jo, Seoul (KR); SeongYeong Kim, Busan (KR); Kwanghyun Choi, Seoul (KR)

(21) Appl. No.: 18/218,513

(22) Filed: Jul. 5, 2023

(30) Foreign Application Priority Data
Dec. 16, 2022 (KR) 10-2022-0177269

(51) Int. Cl. G02B 26/00

(52) U.S. Cl. CPC G02B 26/005

(57) ABSTRACT

A display device includes a display panel including a pixel. The display device also includes a light modulator that is disposed on the display panel and includes a lens configured to control a path of light supplied from the display panel. Further, the display device includes a controller that supplies a driving voltage to the light modulator. The shape of the lens changes according to a change in value of the driving voltage.

### CROSS-REFERENCE TO RELATED APPLICATION

This application claims the priority of Republic of Korea Patent Application No. 10-2022-0177269 filed on Dec. 16, 2022, in the Korean Intellectual Property Office, which is hereby incorporated by reference in its entirety.

### BACKGROUND

### Field

The present disclosure relates to a display device, and more particularly, to a light-emitting display device having a controllable viewing angle.

### Description of the Related Art

An organic light-emitting diode (OLED) serving as a self-emitting element includes an anode electrode, a cathode electrode and an organic compound layer formed between the anode electrode and the cathode electrode. The organic compound layer includes a hole transport layer (HTL), an emission layer (EML) and an electron transport layer (ETL). When a voltage is applied to the anode electrode and the cathode electrode, holes passing through the HTL and electrons passing through the ETL move to the EML and form excitons. As a result, the EML generates light. An active matrix display device includes OLEDs capable of emitting light by itself and has advantages of fast response time, high emission efficiency, high luminance and wide viewing angle. Thus, the active matrix display device has been used in various fields. The display device includes pixels each including the OLED and arranged in a matrix form, and the luminance of the pixels may be adjusted depending on a gray scale of video data.

Meanwhile, the display device is not limited in viewing angle, but has recently been required to have a limited viewing angle for reasons of privacy protection and information protection.

Also, when the display device is used to provide vehicle driving information, an image displayed by the display device may be reflected from a window of a vehicle and thus may block a driver's view. Such reflection of the image in the vehicle is particularly severe during driving at night and may adversely affect the driver's safe driving. Therefore, a display device to be applied to a vehicle is required to have a limited viewing angle.

Meanwhile, such limitation of viewing angle varies depending on whether a vehicle is driven and whether a driver and a passenger are viewing the display device. Therefore, a viewing angle needs to be selectively switched. Also, in some countries, exposure of multimedia played back in front of a passenger seat to a driver is prohibited. Therefore, a viewing angle needs to be selectively switched.

### SUMMARY

An object to be achieved by the present disclosure is to provide a display device in which a viewing angle of a display image may be controlled.

Another object to be achieved by the present disclosure is to provide a display device with improved aperture ratio and luminance.

Yet another object to be achieved by the present disclosure is to provide a display device with a reduced non-display area.

In one embodiment, a display device comprises: a display panel including a pixel; a light modulator on the display panel, the light modulator including a lens that overlaps the pixel and is configured to control a path of light supplied from the pixel; and a controller configured to supply a driving voltage to the light modulator, wherein a shape of the lens changes according to a change in value of the driving voltage.

In one embodiment, a display device comprises: a display panel including a plurality of pixels; and a light modulator on the display panel, the light modulator including a plurality of lenses that each overlap a corresponding one of the plurality of pixels, wherein the display device is configured to switch between a first mode having a first viewing angle and a second mode having a second viewing angle that is different from the first viewing angle, and during the first mode a lens from the plurality of lenses has a first shape and during the second mode the lens has a second shape that is different from the first shape.

In one embodiment, a display device comprises: a display panel including a plurality of pixels; and a light modulator on the display panel, the light modulator including an insulating layer and a plurality of lenses on the insulating layer, each of the plurality of lenses overlapping a corresponding one of the plurality of pixels; and a controller configured to supply one of a first driving voltage to the light modulator and a second driving voltage to the light modulator, wherein a first contact angle is formed between the insulating layer and a part of a lens that is in contact with the insulating layer with respect to a reference that is perpendicular to the insulating layer responsive to the first driving voltage, and a second contact angle that is different from the first contact angle is formed between the insulating layer and the part of the lens with respect to the reference responsive to the second driving voltage.

Objects of the present disclosure are not limited to the above-mentioned objects, and other objects, which are not mentioned above, can be clearly understood by those skilled in the art from the following descriptions.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 illustrates a display device according to exemplary embodiments of the present disclosure;

FIG. 2 is a block diagram showing an example of a controller included in the display device of FIG. 1 according to exemplary embodiments of the present disclosure;

FIG. 3 is a circuit diagram showing an example of a pixel included in the display device of FIG. 1 according to exemplary embodiments of the present disclosure;

FIG. 4 is a waveform chart showing an example of signals applied to the pixel of FIG. 3 according to exemplary embodiments of the present disclosure;

FIG. 5 is a plan view of the display device according to exemplary embodiments of the present disclosure;

FIG. 6 is a cross-sectional view of the display device according to exemplary embodiments of the present disclosure;

FIG. 7 is a cross-sectional view of the display device according to exemplary embodiments of the present disclosure;

FIG. 8A through FIG. 8C explain electrowetting involved in driving of the display device according to exemplary embodiments of the present disclosure;

FIG. 9A is a waveform chart explaining an example in which the display device of FIG. 6 operates in a first mode according to exemplary embodiments of the present disclosure;

FIG. 9B is a cross-sectional view for explaining the example in which the display device of FIG. 6 operates in the first mode according to exemplary embodiments of the present disclosure;

FIG. 10A is a waveform chart for explaining an example in which the display device of FIG. 6 operates in a second mode according to exemplary embodiments of the present disclosure;

FIG. 10B is a cross-sectional view for explaining the example in which the display device of FIG. 6 operates in the second mode according to exemplary embodiments of the present disclosure;

FIG. 11A illustrates a gate driver according to Comparative Embodiment of the present disclosure;

FIG. 11B illustrates a gate driver according to an exemplary embodiment of the present disclosure;

FIG. 12 illustrates an example of the display device of FIG. 1 according to exemplary embodiments of the present disclosure;

FIG. 13A is provided to explain an example in which the display device of FIG. 12 operates in a normal mode according to exemplary embodiments of the present disclosure;

FIG. 13B is provided to explain an example in which the display device of FIG. 12 operates in a partial mode according to exemplary embodiments of the present disclosure; and

FIG. 14 illustrates an example of the display device of FIG. 1 according to exemplary embodiments of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

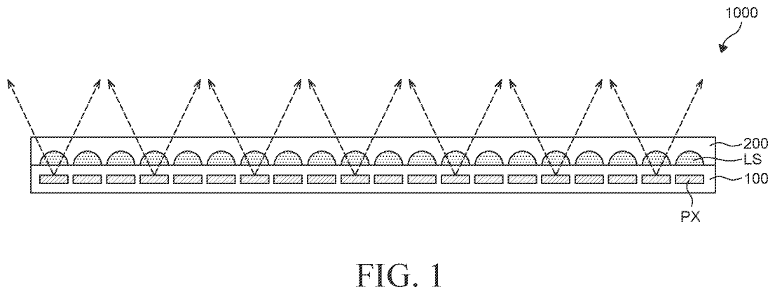

FIG. 1 illustrates a display device according to exemplary embodiments of the present disclosure.

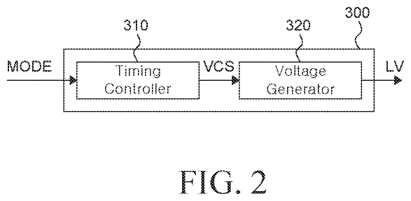

FIG. 2 is a block diagram showing an example of a controller included in the display device of FIG. 1 according to exemplary embodiments of the present disclosure.

Referring to FIG. 1, a display device 1000 according to exemplary embodiments of the present disclosure may include a display panel 100 and a light modulator 200. In an exemplary embodiment, the display device 1000 may further include a controller (e.g., a controller 300 of FIG. 2).

The display panel 100 may include pixels PX that emit light to display an image. In an exemplary embodiment, each of the pixels PX may emit at least one of red light, green light and blue light. However, this is merely an example, and the colors of light emitted from the pixels PX are not limited thereto. For example, light of various colors may be emitted from the pixels PX to implement full color.

In an exemplary embodiment, the display panel 100 may be connected to a driving circuit that drives the pixels PX. The driving circuit may perform a function of at least one of a gate driver, a data driver and a timing controller.

The driving circuit may drive the pixels PX of the display panel 100 based on image data supplied from the controller 300 (see FIG. 2). For example, the driving circuit may supply the pixels PX with a gate signal, a data signal, etc. for displaying an image based on the image data.

The pixels PX may be disposed on the entire surface of the display panel 100 to form an emission surface. An image may be displayed through the pixels PX.

The display panel 100 may include a display layer disposed on a predetermined substrate to form pixels PX. The display layer may include a pixel circuit layer and a display element layer. The display panel 100 may further include an encapsulation structure that encapsulates the display element layer. The display panel 100 may also include a polarization layer including a retarder and/or a polarizer on the encapsulation structure.

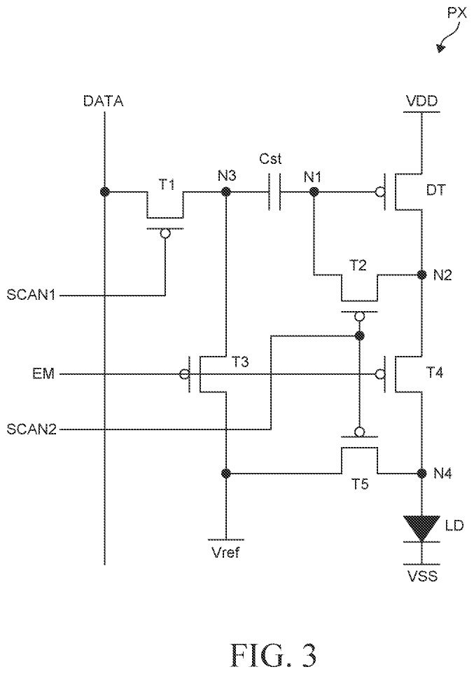

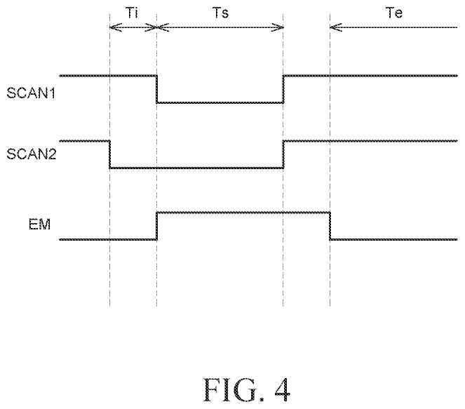

The pixel circuit layer may include a pixel circuit configured to drive a light-emitting diode (LED) of a pixel PX. For example, the pixel circuit layer may include transistors and signal lines/power supply lines connected to the transistors. The pixel circuit layer may have a laminated structure for forming the transistors. A circuit and driving of the pixel circuit will be described in detail with reference to FIG. 3 and FIG. 4.

The display element layer may be disposed on the pixel circuit layer. The display element layer may include light emitting diodes (LEDs). The LEDs may be electrically connected to pixel circuits of the pixel circuit layer. In an exemplary embodiment, the LEDs may be self-emitting elements. The self-emitting elements may include organic LED, inorganic LEDs, or LEDs made of an inorganic material and an organic material. That is, the display panel 100 may be a self-emitting display panel. However, this is merely an example, and the LEDs may also include LEDs (e.g., quantum dot display elements) that emit light with a wavelength adjusted by using quantum dots.

The display panel 100 may be implemented with a liquid crystal display panel, a plasma display panel, a display panel that displays an image using quantum dots, or the like.

The light modulator 200 may be disposed on the display panel 100.

In an exemplary embodiment, the display panel 100 and the light modulator 200 may control a viewing angle of a display image under control of the controller 300 (see FIG. 2). For example, the light modulator 200 may control a path of light supplied from the display panel 100 under control of the controller 300 (see FIG. 2). Thus, a viewing angle of a display image may be controlled.

Also, the light modulator 200 may control the viewing angle of the display image for each display area. For example, the light modulator 200 differently controls light supplied from the display panel 100 for each area under control of the controller 300 (see FIG. 2). Thus, the viewing angle of the display image may be controlled differently for each display area.

In some exemplary embodiments, the light modulator 200 may include a lens layer including a plurality of lenses LS. The lenses LS may be disposed on the pixels PX, respectively, of the display panel 100 to refract light supplied from the pixels PX in a specific direction.

Each lens LS may be a liquid lens having a half-spherical lens. Therefore, light supplied into the lens LS may be refracted in a specific direction on a surface of the lens LS. However, this is merely an example, and the shape of the lens LS is not limited thereto.

In an exemplary embodiment, the shape of the lens LS may be changed (or controlled) under control of the controller 300 (see FIG. 2).

For example, referring to FIG. 2, the controller 300 may include a timing controller 310 and a voltage generator 320 (e.g., a circuit).

The timing controller 310 may control the overall operation of the display device 1000. For example, as described above, the timing controller 310 may be supplied with input image data, control signals, etc. from the outside (e.g., a host system) to control the gate driver and the data driver based on the received data and signals.

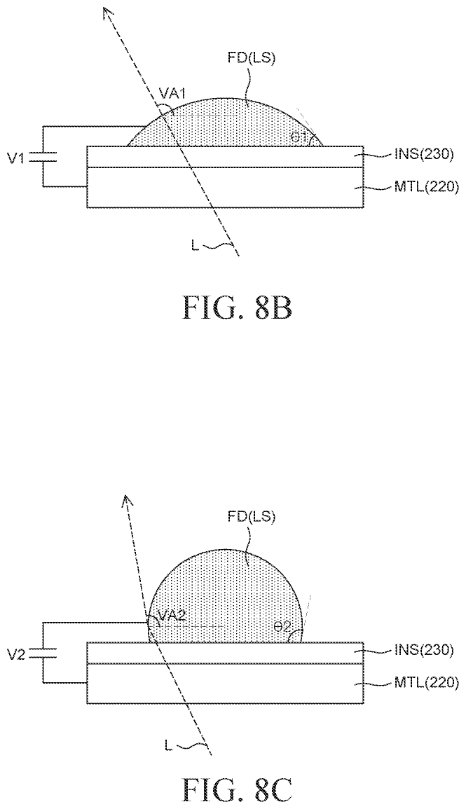

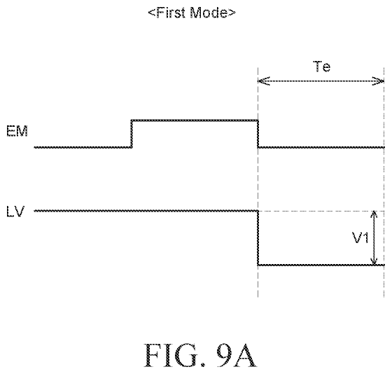

In an exemplary embodiment, the timing controller 310 may be supplied with a mode signal MODE from the outside (e.g., the host system). The mode signal MODE may be a signal for controlling an image display mode of the display device 1000. Herein, as described above, the viewing angle of the display image may be controlled and/or the viewing angle of the display image may be controlled differently for each display area depending on the image display mode. This will be described in more detail with reference to FIG. 9A through FIG. 10B and FIG. 12 through FIG. 14.

The timing controller 310 may generate a voltage control signal VCS based on the mode signal MODE and supply the voltage control signal VCS to the voltage generator 320.

The voltage generator 320 may generate a driving voltage LV having a voltage value depending on the image display mode of the display device 1000 based on the voltage control signal VCS. The voltage generator 320 may generate a plurality of driving voltages LV having different values where each value corresponds to a respective display mode of the display device 1000. The voltage generator 320 may supply the driving voltage LV to a light controller 200.

Referring back to FIG. 1, the driving voltage LV supplied from the voltage generator 320 may be supplied to an electrode pattern included in the light modulator 200. Herein, the electrode pattern may be disposed under the lenses LS (or the lens layer).

When the driving voltage LV is supplied to the electrode pattern, an electric field is generated between the lenses LS and the electrode pattern. In this case, a surface tension of the lens LS is changed by electrowetting and the shape of the lens LS may be changed (or controlled) from a first shape to a second shape. When the shape of the lens LS is changed, light supplied into the lens LS may be refracted at a changed angle on the surface of the lens LS. As described above, the display device 1000 according to exemplary embodiments of the present disclosure controls the shapes of the lenses LS included in the light modulator 200. Thus, it is possible to control the viewing angle of the display image and/or possible to differently control the viewing angle of the display image for each display area.

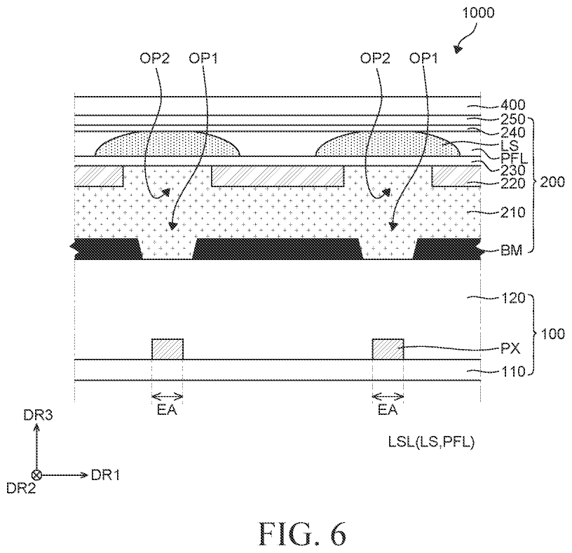

A configuration for controlling the shapes of the lenses LS included in the light modulator 200 will be described in more detail with reference to FIG. 6 through FIG. 10B.

FIG. 3 is a circuit diagram showing an example of a pixel included in the display device of FIG. 1 according to exemplary embodiments of the present disclosure.

Switch elements constituting each of the pixels PX may be implemented with a transistor having an n-type or p-type MOSFET structure. Meanwhile, for the convenience of description, a p-type transistor is illustrated in the following exemplary embodiment, but the exemplary embodiment of the present disclosure is not limited thereto. For example, at least some of the switch elements constituting each of the pixels PX may be changed to n-type transistors.

Also, the transistor may be a three-electrode element including a gate electrode, a source electrode and a drain electrode. The source electrode may be an electrode that supplies carriers to the transistor. The carriers may start to flow from the source electrode within the transistor. The drain electrode may be an electrode in which the carriers in the transistor are discharged to the outside. That is, in a MOSFET, the carriers may flow from the source electrode to the drain electrode. In an n-type MOSFET (NMOS), the carriers are electrons, and, thus, a voltage of the source electrode is lower than a voltage of the drain electrode to enable the electrons to flow from the source electrode to the drain electrode. In the n-type MOSFET, the electrons flow from the source electrode toward the drain electrode, and, thus, a current may flow from the drain electrode toward the source electrode. In a p-type MOSFET (PMOS), the carriers are holes, and, thus, a voltage of the source electrode is higher than a voltage of the drain electrode to enable the holes to flow from the source electrode to the drain electrode. In the p-type MOSFET, the holes flow from the source electrode toward the drain electrode, and, thus, a current may flow from the source electrode toward the drain electrode. It should be noted that the source electrode and the drain electrode of the MOSFET are not fixed. For example, the source electrode and the drain electrode of the MOSFET may be changed depending on an applied voltage. That is, in the following exemplary embodiment, it should be noted that the present disclosure is not limited by the source electrode and the drain electrode of the transistor.

Referring to FIG. 3, each pixel PX may include a light emitting element LD such as a LED, a driving transistor DT, first to fifth transistors T1 to T5 and a storage capacitor Cst.

A first electrode (e.g., an anode electrode) of the light emitting element LD may be connected to a fourth node N4 (or the fourth transistor T4 and the fifth transistor T5). Also, a second electrode (e.g., a cathode electrode) may be connected to a low-potential voltage line that supplies a low-potential voltage VSS. The light emitting element LD may generate light (i.e., emit light) of a predetermined luminance in response to the amount of current (or driving current) supplied from the driving transistor DT.

Meanwhile, for the convenience of description, FIG. 3 illustrates that a pixel PX includes a single light emitting element LD according to an exemplary embodiment. However, this is merely an example, and the exemplary embodiment of the present disclosure is not limited thereto. For example, the pixel PX may include a plurality of light emitting elements, and the plurality of light emitting elements may be connected to each other in series, in parallel or in a combination of serial and parallel connections.

A first electrode (e.g., a source electrode) of the driving transistor DT may be connected to a high-potential voltage line that supplies a high-potential voltage VDD. Also, a second electrode (e.g., a drain electrode) may be connected to a second node N2. Further, a gate electrode of the driving transistor DT may be connected to a first node N1. The driving transistor DT may control a driving current (e.g., the amount of driving current) flowing from the high-potential voltage line that supplies the high-potential voltage VDD to the low-potential voltage line that supplies the low-potential voltage VSS through the light emitting element LD in response to its gate-source voltage Vgs. To this end, the high-potential voltage VDD may be set higher than the low-potential voltage VSS. For example, the high-potential voltage VDD may be a positive voltage, and the low-potential voltage VSS may be a ground voltage. However, this is merely an example, and the exemplary embodiment of the present disclosure is not limited thereto. The low-potential voltage VSS may also be set as a negative voltage.

The first transistor T1 may be connected to a data line that supplies a data signal DATA and a third node N3. For example, a first electrode (e.g., a source electrode) of the first transistor T1 may be connected to the data line, and a second electrode (e.g., a drain electrode) may be connected to the third node N3. Also, a gate electrode of the first transistor T1 may be connected to a first scan signal line that supplies a first scan signal SCAN1. When the first scan signal SCAN1 of a turn-on level (e.g., low level) is supplied to the first scan signal line, the first transistor T1 may be turned on to electrically connect the data line and the third node N3. In this case, the data signal DATA supplied through the data line may be applied to the third node N3 (e.g., one electrode of the storage capacitor Cst).

The second transistor T2 may be connected between the gate electrode and the second electrode (e.g., the drain electrode) of the driving transistor DT (e.g., between the first node N1 and the second node N2). For example, a first electrode (e.g., a source electrode) of the second transistor T2 may be connected to the second node N2 corresponding to the second electrode of the driving transistor DT. Also, a second electrode (e.g., a drain electrode) may be connected to the first node N1 corresponding to the gate electrode of the driving transistor DT. Further, a gate electrode of the second transistor T2 may be connected to a second scan signal line that supplies a second scan signal SCAN2. When the second scan signal SCAN2 of the turn-on level (e.g., low level) is supplied to the second scan signal line, the second transistor T2 may be turned on to electrically connect the first node N1 and the second node N2 (i.e., the gate electrode and the drain electrode of the driving transistor DT). That is, a timing to connect the gate electrode and the second electrode (e.g., the drain electrode) of the driving transistor DT may be controlled by the second scan signal SCAN2. When the second transistor T2 is turned on, the driving transistor DT may be diode-connected in the form of a diode.

The third transistor T3 may be connected between the third node N3 and a reference voltage line that supplies a reference voltage Vref. For example, a first electrode (e.g., a source electrode) of the third transistor T3 may be connected to the reference voltage line, and a second electrode (e.g., a drain electrode) may be connected to the third node N3. Also, a gate electrode of the third transistor T3 may be connected to an emission signal line that supplies an emission signal EM. When the emission signal EM of the turn-on level (e.g., low level) is supplied to the emission signal line, the third transistor T3 may be turned on to electrically connect the third node N3 to the reference voltage line. In this case, the reference voltage Vref supplied through the reference voltage line may be supplied to the third node N3.

The fourth transistor T4 may be connected between the second node N2 and the fourth node N4. For example, a first electrode (e.g., a source electrode) of the fourth transistor T4 may be connected to the second node N2 (or the second electrode of the driving transistor DT). Also, a second electrode (e.g., a drain electrode) may be connected to the fourth node N4 (or the first electrode of the light emitting element LD). Further, a gate electrode of the fourth transistor T4 may be connected to the emission signal line that supplies the emission signal EM.

The fourth transistor T4 may control an electrical connection between the driving transistor DT and the LED LD to form or block a current path. For example, when the emission signal EM of the turn-on level (e.g., low level) is supplied to the emission signal line, the fourth transistor T4 may be turned on to electrically connect the second node N2 and the fourth node N4. In this case, a current path may be formed between the driving transistor DT and the light emitting element LD. Also, when the emission signal EM of a turn-off level (e.g., high level) is supplied to the emission signal line, the fourth transistor T4 may be turned off. In this case, the current path between the driving transistor DT and the light emitting element LD may be blocked.

The fifth transistor T5 may be connected between the reference voltage line and the first electrode of the light emitting element LD (or the fourth node N4). For example, a first electrode (e.g., a source electrode) of the fifth transistor T5 may be connected to the reference voltage line, and a second electrode (e.g., a drain electrode) may be connected to the fourth node N4. Also, a gate electrode of the fifth transistor T5 may be connected to the second scan signal line. When the second scan signal SCAN2 of the turn-on level (e.g., low level) is supplied to the second scan signal line, the fifth transistor T5 may be turned on to electrically connect the first electrode of the light emitting element LD (or the fourth node N4) to the reference voltage line. In this case, the reference voltage Vref supplied through the reference voltage line may be supplied to the first electrode of the light emitting element LD (or the fourth node N4).

The storage capacitor Cst may be connected between the gate electrode of the driving transistor DT (or the first node N1) and the third node N3. For example, the storage capacitor Cst may include a first electrode connected to the gate electrode of the driving transistor DT and a second electrode connected to the third node N3. Thus, the storage capacitor Cst may store a voltage corresponding to a voltage difference between the first node N1 and the third node N3.

FIG. 4 is a waveform chart showing an example of signals applied to the pixel of FIG. 3 according to an exemplary embodiment of the present disclosure.

Referring to FIG. 3 and FIG. 4, the pixel PX according to an exemplary embodiment of the present disclosure may operate in a period divided into an initial period Ti, a sampling period Ts and an emission period Te. Herein, the initial period Ti is a period in which a voltage of the first node N1, which is the gate electrode of the driving transistor DT, is initialized. The sampling period Ts is a period in which a threshold voltage of the driving transistor DT is sampled and a voltage corresponding to the data signal DATA is programmed. The emission period Te is a period in which the light emitting element LD emits light in response to a driving current corresponding to a programmed gate-source voltage of the driving transistor DT.

More specifically, during the initial period Ti, the first scan signal SCAN1 may be at the turn-off level (e.g., high level), the second scan signal SCAN2 may be at the turn-on level (e.g., low level), and the emission signal EM may be at the turn-on level (e.g., low level).

Therefore, during the initial period Ti, the fifth transistor T5 may be turned on in response to the second scan signal SCAN2 of the turn-on level. Thus, the reference voltage Vref may be applied to the first electrode (e.g., the anode electrode) of the light emitting element LD. Accordingly, the first electrode (e.g., the anode electrode) of the light emitting element LD may be initialized to the reference voltage Vref.

Also, the second transistor T2 and the fourth transistor T4 are turned on in response to the second scan signal SCAN2 and the emission signal EM of the turn-on level. Thus, the reference voltage Vref may be applied to the first node N1 and the second node N2. Accordingly, the gate electrode of the driving transistor DT may be initialized to the reference voltage Vref.

Herein, a voltage value of the reference voltage Vref may be selected within a range of voltage sufficiently lower than an operating voltage of the light emitting element LD, and may be selected to be equal to or lower than the low-potential voltage VSS.

Further, the third transistor T3 is turned on in response to the emission signal EM of the turn-on level. Thus, the reference voltage Vref may be applied to the third node N3. Accordingly, the reference voltage Vref may be applied to the first electrode of the storage capacitor Cst.

Then, during the sampling period Ts, each of the first scan signal SCAN1 and the second scan signal SCAN2 may be at the turn-on level (e.g., low level), and the emission signal EM may be at the turn-off level (e.g., high level).

Therefore, the first transistor T1 may be turned on in response to the first scan signal SCAN1 of the turn-on level. Thus, the data signal DATA may be applied to the third node N3. Also, the second transistor T2 may be turned on or may maintain a turn-on state in response to the second scan signal SCAN2 of the turn-on level. Thus, the driving transistor DT may be diode-connected in the form of a diode and the gate electrode and the second electrode (e.g., the drain electrode) of the driving transistor DT may be short-circuited. Therefore, the driving transistor DT may operate like a diode.

A current may flow between the source electrode and the drain electrode of the driving transistor DT. Herein, the gate electrode and the drain electrode (second electrode) of the driving transistor DT are in a state of diode-connection. Thus, a voltage of the first node N1 may rise until the gate-source voltage of the driving transistor DT becomes the threshold voltage, by the current flowing from the source electrode (first electrode) to the drain electrode (second electrode). As such, during the sampling period Ts, the voltage of the first node N1 may be charged with a voltage corresponding to the sum of a voltage corresponding to the data signal DATA and the threshold voltage of the driving transistor DT.

Thereafter, during the emission period Te, each of the first scan signal SCAN1 and the second scan signal SCAN2 may be at the turn-off level (e.g., high level), and the emission signal EM may be at the turn-on level (e.g., low level).

Therefore, the third transistor T3 is turned on in response to the emission signal EM of the turn-on level. Thus, the reference voltage Vref may be applied to the third node N3. Also, a voltage difference of the third node N3 (e.g., a value corresponding to a difference between the voltage corresponding to the data signal DATA and the reference voltage Vref) may be applied to the first node N1 due to coupling through the capacitor Cst.

Also, during the emission period Te, the fourth transistor T4 may be turned on in response to the emission signal EM of the turn-on level to form a current path between the driving transistor DT and the LED LD. Therefore, a driving current may be applied to the LED LD, and the LED LD may emit light.

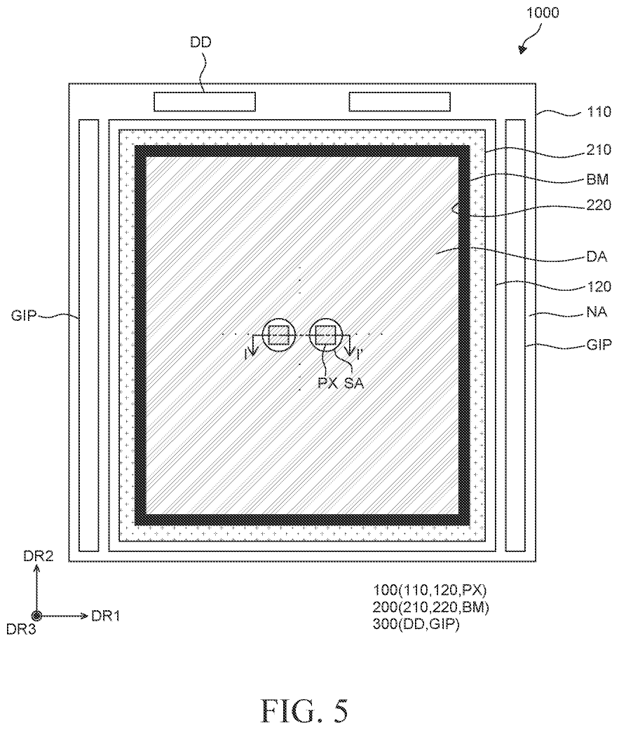

FIG. 5 is a plan view of the display device according to exemplary embodiments of the present disclosure.

Referring to FIG. 5, the display device 1000 according to exemplary embodiments of the present disclosure may include the display panel 100, the light modulator 200 and the controller 300.

The display device 1000 may be provided in various shapes. For example, the display device 1000 may be provided in a rectangular plate shape having two pairs of parallel sides, but the exemplary embodiment of the present disclosure is not limited thereto. If the display device 1000 is provided in a rectangular plate shape, one pair of the two pairs of sides may be longer than the other pair. For the convenience of description, FIG. 5 illustrates that the display device 1000 has a rectangular shape with a pair of long sides and a pair of short sides. Also, FIG. 5 illustrates that the pair of long sides extends in a second direction DR2 and the pair of short sides extends in a first direction DR1. In some exemplary embodiments, the display device 1000 provided in a rectangular plate shape may also have a rounded corner between each long side and the short side. However, the present disclosure is not limited thereto. The display device 1000 may also have a square shape, a polygonal shape, a circular shape, etc.

The display device 1000 may display an image through a display surface. The display surface may be parallel to a surface defined by a first directional axis corresponding to the first direction DR1 and a second directional axis corresponding to the second direction DR2. A normal direction of the display surface, i.e., a thickness direction of the display device 1000, is defined as a third direction DR3.

A front surface (or an upper surface) and a back surface (or a lower surface) of each of members, layers or units described below may be distinguished along the third direction DR3. However, the first to third directions DR1, DR2 and DR3 are merely examples, and the first to third directions DR1, DR2 and DR3 may be interchanged as relative concepts.

The display panel 100 may include a display area DA and a non-display area NA. The display area DA is provided with the pixels PX and thus may display an image, and the non-display area NA may be located outside the display area DA. For example, the non-display area NA may be provided to surround the display area DA.

The display panel 100 may include a base layer 110 (or a lower substrate), an encapsulation layer 120 and the pixels PX. The pixels PX may be provided in the display area DA of the display panel 100. For example, the pixels PX may be disposed on the base layer 110 of the display panel 100 and may form the display area DA. Also, the encapsulation layer 120 may be disposed on the pixels PX to protect the pixels PX against moisture and oxygen.

The pixels PX included in the display panel 100 may be disposed in a lattice form to be spaced apart from each other along the first direction DR1 and the second direction DR2. In an exemplary embodiment, the pixels PX may form a plurality of pixel rows and a plurality of pixel columns. Herein, each of the pixel rows may refer to a pixel group connected to the same gate line, and each of the pixel columns may refer to a pixel group connected to the same data line. For example, each pixel row may be defined by the pixels PX aligned in the first direction DR1, and each pixel column may be defined by the pixels PX aligned in the second direction DR2. The pixel rows may be aligned along the second direction DR2, and the pixel columns may be aligned along the first direction DR1.

The non-display area NA of the display panel 100 surrounds at least one side of the display area DA, and may refer to an area except the display area DA. In some exemplary embodiments, the non-display area NA may include a line area, a pad area and/or various dummy areas. For example, a data driver DD, a gate driver GIP, etc. included in the controller 300 may be disposed in the non-display area NA.

The data driver DD and the gate driver GIP included in the controller 300 may drive the pixels PX disposed in the display area DA. For example, as described above with reference to FIG. 1 and FIG. 2, the data driver DD may supply a data signal to the pixels PX and the gate driver GIP may supply a gate signal to the pixels PX under control of the timing controller 310 (see FIG. 2).

The light modulator 200 may be disposed on the display panel 100. In an exemplary embodiment, the light modulator 200 may include an optical gap layer 210, an electrode pattern 220 and a light blocking pattern BM. Also, as described above with reference to FIG. 1 and FIG. 2, the light modulator 200 includes the lens layer including the plurality of lenses LS (see FIG. 1) and thus may refract light supplied from the display panel 100 in a specific direction. The shapes of the lenses LS (see FIG. 1) of the light modulator 200 may be changed under control of the controller 300 to control a viewing angle of a display image.

The specific cross-sectional structures of the display panel 100 and the light modulator 200 and a configuration of the light modulator 200 for controlling a viewing angle will be described in detail with reference to FIG. 6 through FIG. 10B.

Meanwhile, light emitted from each pixel PX of the display panel 100 may form a viewing area SA corresponding to the pixel PX. For example, when light is emitted from a pixel PX of the display panel 100 and supplied to a user through the light modulator 200, the light modulator 200 controls a viewing angle. Thus, the size (or the area) of the viewing area SA may be changed. For example, as the viewing angle decreases, the size (or the area) of the viewing area SA may decrease, and as the viewing angle increases, the size (or the area) of the viewing area SA may also increase. Herein, as the size (or the area) of each viewing area SA increases, a viewing angle of a display image supplied to the user may increase. Also, as the size (or the area) of each viewing area SA decreases, the viewing angle of the display image supplied to the user may decrease.

FIG. 6 is a cross-sectional view of the display device according to exemplary embodiments of the present disclosure.

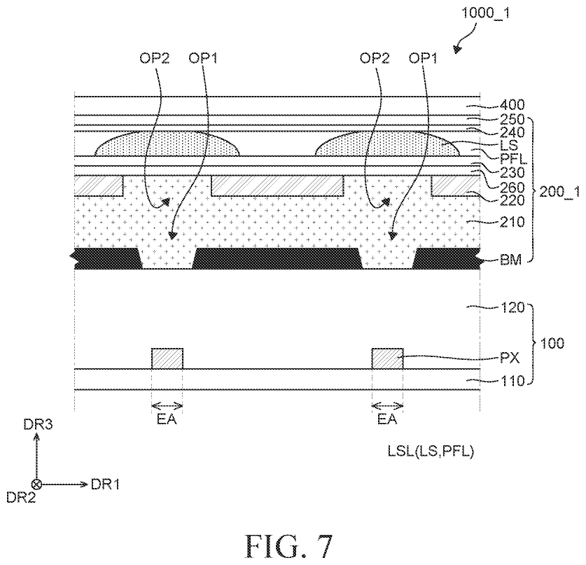

FIG. 7 is a cross-sectional view of the display device according to exemplary embodiments of the present disclosure.

The cross-sectional structures of the display device 1000 shown in FIG. 6 and FIG. 7 are taken along a line I-I′ of the display device 1000 of FIG. 5.

Referring to FIG. 1, FIG. 2, FIG. 5 and FIG. 6, the display device 1000 according to an exemplary embodiment of the present disclosure may include the display panel 100 and the light modulator 200 disposed on the display panel 100. In some exemplary embodiments, the display device 1000 may further include an upper substrate 400 disposed on the light modulator 200.

The display panel 100 may include the base layer 110 (or the lower substrate), the pixels PX and the encapsulation layer 120.

The base layer 110 is a base substrate of the display panel 100, and may be a light-transmitting substrate which is substantially transparent. The base layer 110 may be a rigid substrate including glass or tempered glass, or a flexible substrate made of plastic. However, the material of the base layer 110 is not limited thereto, and the base layer 110 may be made of various materials.

The pixels PX may be disposed on the base layer 110. In an exemplary embodiment, each of the pixels PX may emit at least one of red light, green light and blue light. However, this is merely an example, and light of various colors may be emitted from the pixels PX to implement full color.

Each of the pixels PX includes at least one light emitting element LD (see FIG. 3), and an emission area EA of the pixel PX may be defined by an area where the LED LD (see FIG. 3) is disposed. That is, each pixel PX (or the light emitting element LD of each pixel PX) may be disposed corresponding to the emission area EA.

The encapsulation layer 120 that has a flat upper surface and covers the pixels PX may be disposed on the pixels PX. The encapsulation layer 120 may protect the pixels PX against moisture and oxygen.

The encapsulation layer 120 may have a sufficient thickness to cover the pixels PX. For example, the encapsulation layer 120 may have a thickness of 3 μm to 20 μm (e.g., 12 μm), but is not limited thereto. The thickness of the encapsulation layer 120 may vary depending on design choice.

The encapsulation layer 120 may include at least one inorganic layer and at least one organic layer. For example, the encapsulation layer 120 may include an inorganic layer, an organic layer and an inorganic layer sequentially laminated, but layers constituting the encapsulation layer 120 are not limited thereto.

The light modulator 200 may be disposed on the display panel 100. In an exemplary embodiment, the light modulator 200 may include the light blocking pattern BM, the optical gap layer 210 and the electrode pattern 220. Also, the light modulator 200 may include a first insulating layer 230, a lens layer LSL, a second insulating layer 240, a planarization layer PFT, and a first electrode layer 250.

The light blocking pattern BM may be disposed on the encapsulation layer 120 of the display panel 100.

In an exemplary embodiment, the light blocking pattern BM may be disposed between adjacent pixels PX or between adjacent emission areas EA. For example, the light blocking pattern BM includes first openings OP1. The first openings OP1 may be formed corresponding to the emission areas EA, respectively. That is each first opening OP1 overlaps a corresponding emission area EA.

In an exemplary embodiment, each of the first openings OP1 may have a width equal to or greater than that of the emission area EA. For example, the first opening OP1 may have a width of about 12 μm, but is not limited thereto. The width of the first opening OP1 may be designed variously depending on the size (or the width) of the emission area EA formed on the display panel 100.

The light blocking pattern BM may include a light-absorbing material or may be coated with a light absorber to absorb light introduced from the outside. For example, the light blocking pattern BM may include a carbon-based black pigment, but is not limited thereto. The light blocking pattern BM may also include an opaque metal material having a high light absorption rate. Examples of the opaque metal material may include chromium (Cr), molybdenum (Mo), an alloy (MoTi) of Mo and Ti, tungsten (W), vanadium (V), niobium (Nb), tantalum (Ta), manganese (Mn), cobalt (Co) or nickel (Ni). For example, the light blocking pattern BM may be a black matrix.

The light blocking pattern BM may have a minimum thickness to absorb light. For example, the light blocking pattern BM may have a thickness of 1 μm or more, but is not limited thereto.

The optical gap layer 210 may be disposed on the light blocking pattern BM. The optical gap layer 210 secures an optical gap between the pixels PX of the display panel 100 and the lenses LS of the lens layer LSL to allow light emitted from the pixels PX to be refracted by the lenses LS in a specific direction. Thus, the optical gap layer 210 improves the efficiency of the lenses LS. To this end, the optical gap layer 210 may have a thickness of several to several tens of μm. For example, the optical gap layer 210 may have a thickness of 3 μm to 20 μm (e.g., 12 μm), but is not limited thereto. The thickness of the optical gap layer 210 may vary depending on design choice.

The optical gap layer 210 may include an organic insulating material. For example, the optical gap layer 210 may include at least one of photo acryl, benzocyclobutene (BCB), polyimide (PI) and polyamide (PA). However, this is merely an example, and the material of the optical gap layer 210 is not limited thereto.

The first insulating layer 230 may be disposed on the optical gap layer 210. In an exemplary embodiment, the first insulating layer 230 may be disposed directly on the optical gap layer 210.

The first insulating layer 230 may be made of a transparent insulating material or may include an inorganic material. For example, the first insulating layer 230 may include at least one of silicon nitride, silicon oxynitride, silicon oxide, titanium oxide and aluminum oxide, but is not limited thereto.

In some exemplary embodiments, the first insulating layer 230 may have a thickness of 5 μm or less. However, this is merely an example, and the thickness of the first insulating layer 230 is not limited thereto.

Meanwhile, if the first insulating layer 230 is not provided, when the driving voltage LV is supplied to the electrode pattern 220, the lens LS exchanges electrons with the electrode pattern 220 in response to the driving voltage LV. Therefore, the material of the lens LS may be electrolyzed at a relatively low voltage. Herein, the driving voltage LV having a relatively low voltage value may not make a sufficient change in surface tension of the lens LS (for example, the material of the lens LS is electrolyzed at a driving voltage of 1 V or less). Therefore, the first insulating layer 230 is supplied under the lens layer LSL to suppress electrolysis of the material of the lens LS by the driving voltage LV. In this case, even if the driving voltage LV is increased to about 20 V or more, the material of the lens LS is not electrolyzed and the surface tension is sufficiently changed. Therefore, the viewing angle of the display image may be controlled in a wider range.

The electrode pattern 220 may be disposed under the first insulating layer 230.

The electrode pattern 220 may include a transparent conductive material such as ITO. However, the electrode pattern 220 is not limited thereto, and the electrode pattern 220 may also include an opaque conductive material.

The electrode pattern 220 may be supplied with the driving voltage LV for controlling the shapes of the lenses LS of the lens layer LSL.

In an exemplary embodiment, the electrode pattern 220 may be disposed on an area corresponding to the light blocking pattern BM. For example, the electrode pattern 220 includes second openings OP2. The second openings OP2 may be formed corresponding to the first openings OP1, respectively. That is, each second opening OP2 overlaps a corresponding first opening OP1. Herein, as described above, the first opening OP1 is formed corresponding to the emission area EA of the pixel PX, and the second opening OP2 is formed corresponding to the first opening OP1. Therefore, light emitted from the pixel PX may proceed upwards (e.g., in the third direction DR3) through the first opening OP1 and the second opening OP2.

In an exemplary embodiment, each of the second openings OP2 may have a width greater than that of the first opening OP1. For example, the second opening OP2 may have a width greater by about 2 μm to 10 μm than that of the first opening OP1, but is not limited thereto. The width of the second opening OP2 may be designed variously. Since the second opening OP2 has a greater width than the first opening OP1, light emitted from the pixel PX may diffuse and proceed upwards (e.g., in the third direction DR3). Therefore, a sufficient viewing angle (or viewing area) may be secured.

The lens layer LSL may be disposed on the first insulating layer 230. In an exemplary embodiment, the lens layer LSL may include the plurality of lenses LS and a planarization layer PFL. In some exemplary embodiments, the lens layer LSL may have a thickness of 5 μm to 300 μm (e.g., 8 μm), but is not limited thereto. The thickness of the lens layer LSL may vary depending on design choice.

Each of the lenses LS may be disposed on the first insulating layer 230 and disposed to overlap a corresponding one pixel PX. For example, each of the lenses LS may be disposed at least partially overlapping the pixel PX, the first opening OP1 and the second opening OP2 corresponding thereto. Thus, light emitted from the pixel PX may proceed into the lens LS through the first opening OP1 and the second opening OP2. Herein, light supplied into the lens LS may be refracted in a specific direction on a surface of the lens LS. For example, light supplied into the lens LS may be refracted at various angles depending on the shape of the lens LS and the viewing angle of the display image may be controlled accordingly.

In an exemplary embodiment, each of the lenses LS may include a material having polarity. Therefore, when the driving voltage LV is applied, the material of the lens LS has a different polarity from the electrode pattern 220 (or the electrode pattern 220 and a second electrode layer 260 (see FIG. 7)). Thus, the shape of the lens LS may be changed (controlled) by electrowetting.

The planarization layer PFL that covers the lenses LS may be disposed on the lenses LS. The planarization layer PFL may be a member for protecting the lenses LS.

In an exemplary embodiment, the planarization layer PFL may be made of oil having a low refractive index. In order for light supplied into the lens LS and refracted in a specific direction on the surface of the lens LS to proceed in that direction, light should not be refracted inside the planarization layer PFL. Therefore, the planarization layer PFL may be made of oil having a low refractive index. For example, the planarization layer PFL may have a refractive index that is less than the refractive index of the lenses LS. However, the planarization layer PFL is not limited thereto, and the planarization layer PFL may also include an organic insulating material having a lower refractive index than the lenses LS.

In an exemplary embodiment, the material of the planarization layer PFL may have non-polar properties. If the planarization layer PFL includes a polar material, when the driving voltage LV is applied onto the electrode pattern 220 and the first electrode layer 250, the planarization layer PFL may affect the polarity of the lenses LS. Thus, the above-described electrowetting may not normally occur. Therefore, the planarization layer PFL may be made of a material having non-polar properties.

The second insulating layer 240 may be disposed on the lens layer LSL.

The second insulating layer 240 may be made of a transparent insulating material or may include an inorganic material. For example, the second insulating layer 240 may include at least one of silicon nitride, silicon oxynitride, silicon oxide, titanium oxide and aluminum oxide, but is not limited thereto.

In some exemplary embodiments, the second insulating layer 240 may have a thickness of 5 μm or less. However, this is merely an example, and the thickness of the second insulating layer 240 is not limited thereto.

The first electrode layer 250 may be disposed on the second insulating layer 240. The first electrode layer 250 may include a transparent conductive material such as ITO, but is not limited thereto.

The driving voltage LV for controlling the shapes of the lenses LS of the lens layer LSL may be supplied to the first electrode layer 250. That is, the driving voltage LV is supplied between the first electrode layer 250 disposed on the lens layer LSL and the electrode pattern 220 disposed under the lens layer LSL. Thus, an electric field is generated on the surface of the lens LS. Accordingly, the surface tension of the lens LS may be changed by electrowetting described above, and, thus, the shape of the lens LS may be changed (or controlled).

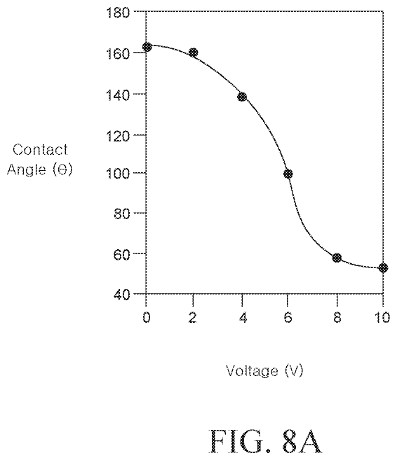

Electrowetting will be described in more detail with reference to FIG. 8A through FIG. 8C.

In some exemplary embodiments, referring to FIG. 7, a light modulator 200_1 of a display device 1000_1 according to an exemplary embodiment of the present disclosure may further include the second electrode layer 260. The second electrode layer 260 is provided between the first electrode layer 250 and the electrode pattern 220. If the light modulator 200_1 further includes the second electrode layer 260, the driving voltage LV may be applied to the second electrode layer 260 as well as the electrode pattern 220.

The second electrode layer 260 may include a transparent conductive material such as ITO, but is not limited thereto.

Referring back to FIG. 6, the upper substrate 400 may be disposed on the light modulator 200. The upper substrate 400 is configured to protect members and/or layers disposed thereunder. The upper substrate 400 may protect the members and/or layers disposed thereunder against contamination, impacts or scratches from the outside.

In an exemplary embodiment, the upper substrate 400 may include a material substantially identical or similar to that of the base layer 110. However, this is merely an example, and the upper substrate 400 is not limited thereto.

FIG. 8A through FIG. 8C are provided to explain electrowetting involved in driving of the display device according to exemplary embodiments of the present disclosure.

As described above with reference to FIG. 1 through FIG. 7, in the display device 1000 according to exemplary embodiments of the present disclosure, the driving voltage LV is applied to the electrode pattern 220 and the first electrode layer 250 disposed on and under the lens layer LSL. Therefore, the shape of the lens LS may be controlled, and, thus, the viewing angle of the display image may be controlled. This is caused by electrowetting in which the surface tension of a fluid is changed by an electric field applied to a surface of the fluid and the shape of the fluid is changed accordingly.

More specifically, referring to FIG. 8A through FIG. 8C, a fluid FD is disposed on a metal layer MTL, and an insulator INS may be disposed between the metal layer MTL and the fluid FD. Herein, the fluid FD may correspond to the lens LS described above with reference to FIG. 1 through FIG. 7. Also, the metal layer MTL may correspond to the electrode pattern 220 (or the electrode pattern 220 and the second electrode layer 260) described above with reference to FIG. 1 through FIG. 7. Further, the insulator INS may correspond to the first insulating layer 230 described above with reference to FIG. 1 through FIG. 7. Meanwhile, as described above, the insulator INS may be interposed between the fluid FD and the metal layer MTL to suppress electrolysis caused by the driving voltage LV.

An angle between a surface of a part of the lens (e.g., the fluid FD) and a surface of the insulator INS that are in contact with each other may be defined as a contact angle that is measured with respect to a reference that is perpendicular to the insulator INS. The contact angle between the part of the lens (e.g., fluid FD) and the insulator INS may vary depending on the magnitude of a voltage applied between the fluid FD and the metal layer MTL. As the contact angle changes, the radius of the lens LS changes.

For example, as shown in FIG. 8A, as the magnitude of the voltage applied between the fluid FD and the metal layer MTL increases, the polarities of the fluid FD and the metal layer MTL become strong. Therefore, an attractive force between the fluid FD and the metal layer MTL becomes strong and a surface tension of the fluid FD becomes relatively weak. Accordingly, the fluid FD has a more planar shape on a flat surface and thus, may decrease in contact angle with the insulator INS.

For example, as shown in FIG. 8B, when a first voltage V1, which is a relatively high voltage (e.g., 5 V to 20 V), is applied between the fluid FD and the metal layer MTL, the surface tension of the fluid FD becomes weak. Thus, the fluid FD has a more planar shape on a flat surface. Therefore, the thickness of the fluid FD (e.g., radius of a center point of the lens LS) may decrease, and the contact angle may be a first angle θ1 which is relatively small.

For another example, as shown in FIG. 8C, when a second voltage V2, which is relatively low voltage (e.g., 0 V to 1 V), is applied between the fluid FD and the metal layer MTL, the surface tension of the fluid FD becomes strong. Thus, the fluid FD has a relatively spherical shape. Therefore, the thickness (e.g., radius of a center point of the lens LS) may be increased, and the contact angle may be a second angle θ2 which is relatively large.

Meanwhile, as described above, when the shape and/or thickness of the fluid FD varies depending on the driving voltage, a refraction angle of light L supplied into the fluid FD may be controlled. For example, the light L supplied into the fluid FD is refracted to proceed in a direction perpendicular to a surface in contact with the surface of the fluid FD. When the shape of the fluid FD is changed, the refraction angle of the light L supplied into the fluid FD may be controlled accordingly.

For example, as shown in FIG. 8B, when the fluid FD has a more planar shape on a flat surface due to the first voltage V1 and has a relatively small thickness, the light L proceeding into the fluid FD may be refracted by the fluid FD and may proceed at a larger angle. Therefore, an image displayed by the light L may have a first viewing angle VA1 which is relatively wide with respect to a reference that is perpendicular to the metal layer MTL.

For another example, as shown in FIG. 8C, when the fluid FD has a relatively spherical shape due to the second voltage V2 and has a relatively large thickness, the light L proceeding into the fluid FD may be refracted by the fluid FD and may proceed at a smaller angle with respect to the reference that is perpendicular to the metal layer MTL. Therefore, an image displayed by the light L may have a second viewing angle VA2 which is relatively narrow.

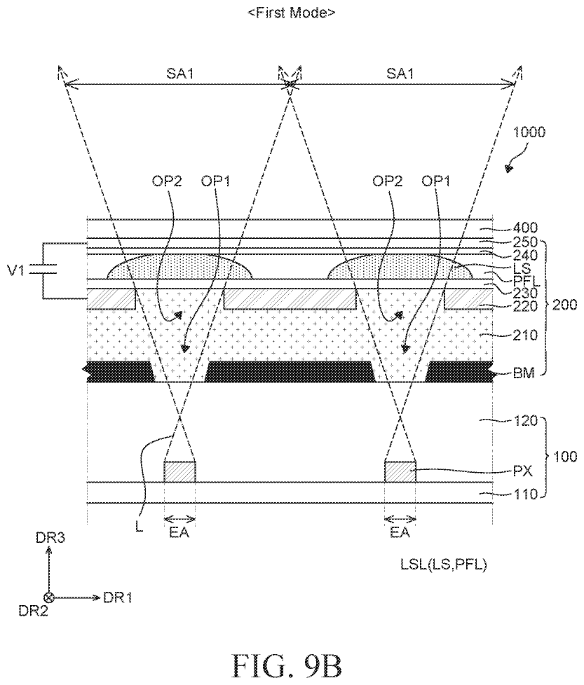

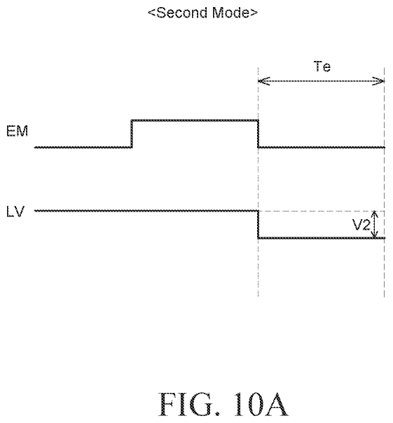

Hereinafter, an operation of the display device 1000 according to exemplary embodiments of the present disclosure affected by electrowetting described above with reference to FIG. 8A through FIG. 8C will be described with reference to FIG. 9A through FIG. 10B.

FIG. 9A is a waveform chart for explaining an example in which the display device of FIG. 6 operates in a first mode according to an exemplary embodiment of the present disclosure.

FIG. 9B is a cross-sectional view for explaining the example in which the display device of FIG. 6 operates in the first mode according to an exemplary embodiment of the present disclosure.

FIG. 10A is a waveform chart for explaining an example in which the display device of FIG. 6 operates in a second mode according to an exemplary embodiment of the present disclosure.

FIG. 10B is a cross-sectional view for explaining the example in which the display device of FIG. 6 operates in the second mode according to an exemplary embodiment of the present disclosure.

Meanwhile, the first mode corresponds to a share mode in which the display device 1000 according to an exemplary embodiment of the present disclosure displays an image at a wide viewing angle. The second mode corresponds to a private mode in which the display device 1000 according to an exemplary embodiment of the present disclosure displays an image at a narrow viewing angle.

First, referring to FIG. 9A and FIG. 9B for explaining an operation of the display device 1000 in the first mode, which is a share mode, the driving voltage LV may be the first voltage V1 during the emission period Te in which the pixel PX emits light in the first mode. In this case, the first voltage V1 may have a voltage value at which the lens LS and the electrode pattern 220 have relatively strong polarities. For example, the first voltage V1 may be in the range of from 5 V to 20 V. However, this is merely an example, and the voltage value of the first voltage V1 is not limited thereto.

Meanwhile, as shown in FIG. 9A, during a period in which the pixel PX does not emit light before the emission period Te, the driving voltage LV may not be supplied or a ground voltage (e.g., 0 V) may be supplied. Therefore, it is possible to suppress unnecessary power consumption.

Referring to FIG. 9B, when the driving voltage LV of the first voltage V1 is applied in the first mode, the lens LS and the electrode pattern 220 may have relatively high values and may have opposite polarities to each other. Thus, a surface tension of the material of the lens LS may become weak due to electrowetting.

In this case, as described above with reference to FIG. 8A through FIG. 8C, the shape of the lens LS may be changed to a first shape, and light emitted from the pixel PX may be refracted by the lens LS at a large refraction angle. For example, the lens LS has a more planar shape (i.e., the lens LS decreases in thickness) on a flat surface (e.g., a surface parallel to the first direction DR1 and the second direction DR2). As shown in FIG. 9B, each lens LS is wider than the second opening OP2. Thus, light L supplied into the lens LS may be refracted by the lens LS and an image displayed by the light L may have a wide viewing angle. Therefore, a viewing area corresponding to each pixel PX may be a first viewing area SA1 which is relatively wide.

Referring to FIG. 10A and FIG. 10B for explaining an operation of the display device 1000 in the second mode, which is a private mode, the driving voltage LV may be the second voltage V2 during the emission period Te in which the pixel PX emits light in the second mode. In this case, the second voltage V2 may have a voltage value at which the lens LS and the electrode pattern 220 have relatively weak polarities or do not have polarities. For example, the second voltage V2 may be in the range of from 0 V to 1 V. However, this is merely an example, and the voltage value of the second voltage V2 is not limited thereto.

Referring to FIG. 10B, when the driving voltage LV of the second voltage V2 is applied in the second mode, the lens LS and the electrode pattern 220 may have relatively weak polarities or do not have polarities. Thus, the surface tension of the material of the lens LS may become strong.

In this case, as described above with reference to FIG. 8A through FIG. 8C, the shape of the lens LS may be changed to the second shape, and light emitted from the pixel PX may be refracted by the lens LS at a small refraction angle. For example, the lens LS has a relatively spherical shape (i.e., the lens LS increases in thickness). As shown in FIG. 10B, each lens LS has a width that substantially matches a width of the second opening OP2. That is, the width of each lens LS in the second mode is narrower than the width of each lens LS in the first mod. Thus, light L supplied into the lens LS may be refracted by the lens LS and an image displayed by the light L may have a narrow viewing angle. Therefore, the viewing area corresponding to each pixel PX may be a second viewing area SA2 which is relatively narrow.

As described above with reference to FIG. 1 through FIG. 10B, the display device 1000 according to exemplary embodiments of the present disclosure includes the lens LS whose shape may be changed depending on the driving voltage LV. Thus, a viewing angle of a display image may be controlled by using the lens LS. Particularly, the shape of the lens LS is not fixed, but changed depending on a value of the driving voltage LV. Therefore, the display device 1000 may exhibit various viewing angles by controlling the value of the driving voltage LV.

Meanwhile, a conventional display device (a display device according to Comparative Embodiment) includes separated emission layers in a pixel including a plurality of anode electrodes for controlling a viewing angle, and lenses having different shapes. Also, the conventional display device selects an emission layer having a corresponding viewing angle depending on a driving mode to display an image. To this end, the conventional display device (the display device according to Comparative Embodiment) includes a plurality of LEDs in each pixel and lenses having different shapes on emission layers, respectively. Therefore, the lenses are disposed in a limited display area, and, thus, the aperture ratio is limited, which results in a limited improvement in luminance. Further, the conventional display device (the display device according to Comparative Embodiment) includes the lenses having different shapes to implement different viewing angles. Therefore, the luminance may become non-uniform depending on the shapes of the lenses.

In contrast, the display device 1000 according to exemplary embodiments of the present disclosure does not include separated emission layers and lenses having different shapes. However, the display device 1000 includes the lens LS whose shape is changed depending on the driving voltage LV to exhibit various viewing angles. Therefore, the aperture ratio may be enhanced, and the luminance may be improved accordingly.

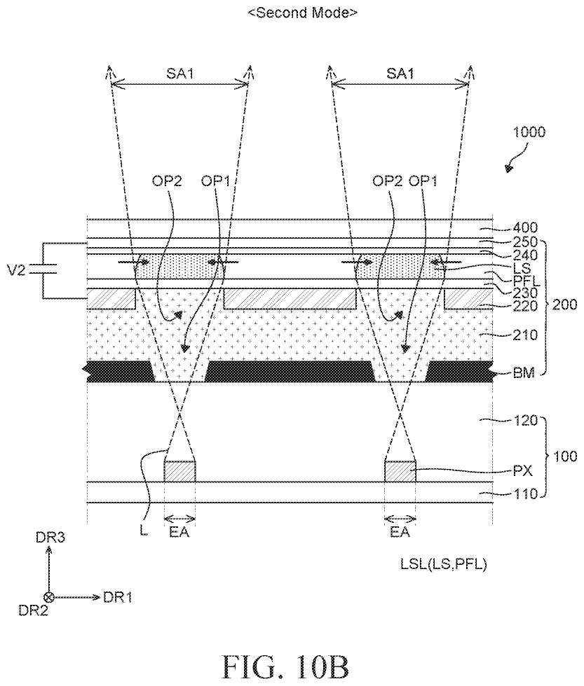

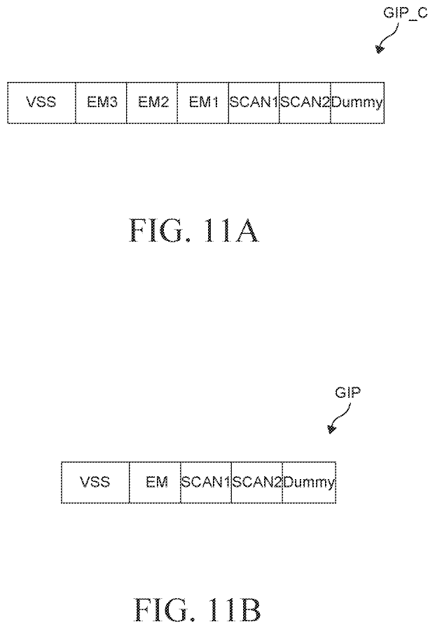

FIG. 11A illustrates a gate driver according to a Comparative Embodiment of the present disclosure.

FIG. 11B illustrates a gate driver according to an exemplary embodiment of the present disclosure.

Referring to FIG. 1 through FIG. 10B, the display device 1000 according to exemplary embodiments of the present disclosure includes the lens LS whose shape is changed depending on the driving voltage LV to control a viewing angle. Therefore, it is possible to control a viewing angle without separated emission layers. That is, even if the pixel PX included in the display device 1000 according to exemplary embodiments of the present disclosure includes only one light emitting element LD, the display device 1000 may control a viewing angle by using the lens LS. However, the conventional display device (the display device according to Comparative Embodiment) includes separated emission layers in a pixel including a plurality of anode electrodes for controlling a viewing angle. Therefore, the conventional display device further needs an emission driver configured to supply an emission signal for separating an emission layer.

For example, referring to FIG. 11A, in the conventional display device (the display device according to Comparative Embodiment), a gate driver GIP_C needs to include at least three emission drivers to supply a first emission signal EM1 for forming a current path and second and third emission signals EM2 and EM3 for separating an emission layer to control the viewing angle. Thus, the gate driver GIP_C has a relatively large area (size). That is, the conventional display device (the display device according to Comparative Embodiment) has a large non-display area.

In contrast, referring to FIG. 11B, the display device 1000 according to exemplary embodiments of the present disclosure includes a single emission driver configured to supply the emission signal EM for forming a current path. Thus, the gate driver GIP may have a relatively small area (size). Therefore, the display device 1000 has a small non-display area NA, which makes it possible to implement a narrow bezel.

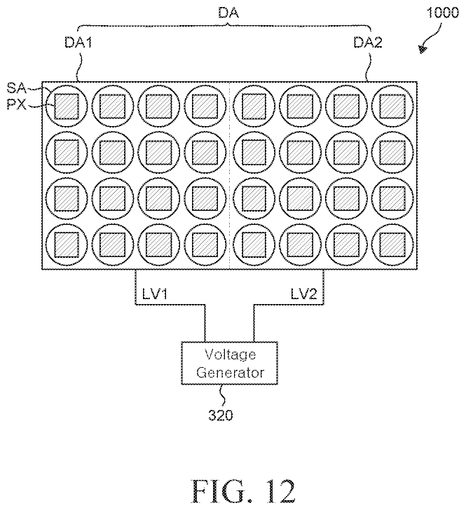

FIG. 12 illustrates an example of the display device of FIG. 1 according to exemplary embodiments of the present disclosure.

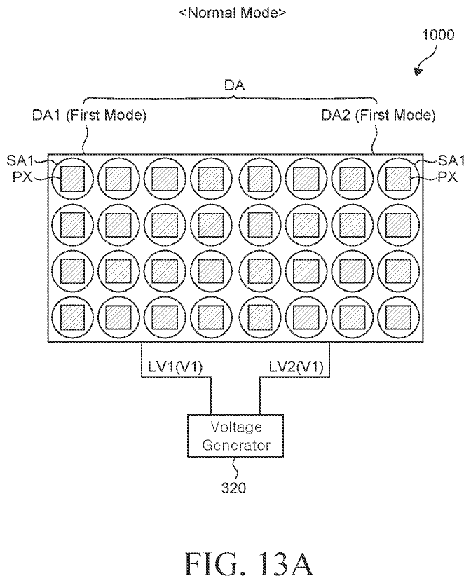

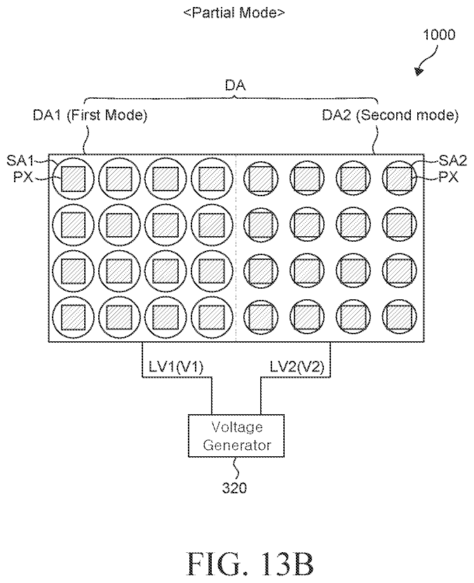

FIG. 13A is provided to explain an example in which the display device of FIG. 12 operates in a normal mode according to exemplary embodiments of the present disclosure.

FIG. 13B is provided to explain an example in which the display device of FIG. 12 operates in a partial mode according to exemplary embodiments of the present disclosure.

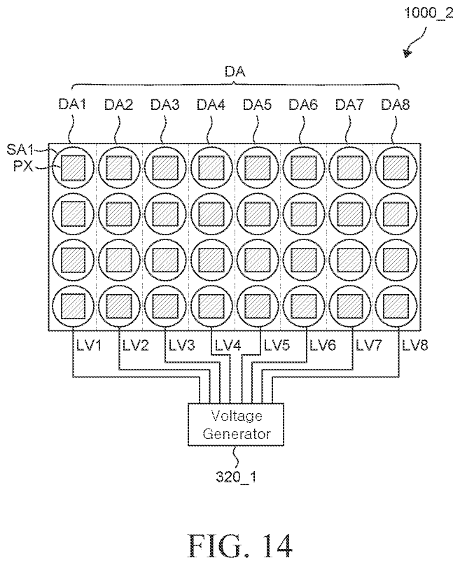

FIG. 14 illustrates an example of the display device of FIG. 1 according to exemplary embodiments of the present disclosure.

Meanwhile, in describing FIG. 12 through FIG. 14, differences from the above-described exemplary embodiment will be mainly described to avoid redundant description. Also, parts which are not particularly described are the same as those of the above-described exemplary embodiment, and the same or similar reference numerals designate the same or similar components.

Referring to FIG. 12, the display device 1000 according to exemplary embodiments of the present disclosure may differently control a viewing angle of a display image for each display area.

For example, the display device 1000 includes the display area DA in which the pixels PX are disposed to display an image. The display area DA may be divided into a first display area DA1 and a second display area DA2.

In an exemplary embodiment, the display device 1000 may individually control viewing angles of the pixels PX disposed in the respective display areas DA1 and DA2 by using the voltage generator 320. For example, in order to control the viewing angles, the display device 1000 may supply a first driving voltage LV1 to the first display area DA1 and a second driving voltage LV2 to the second display area DA2. In this case, the viewing area SA corresponding to each of the pixels PX disposed in the first display area DA1 may be determined by a value of the first driving voltage LV1. Also, the viewing area SA corresponding to each of the pixels PX disposed in the second display area DA2 may be determined by a value of the second driving voltage LV2. Therefore, it is possible to individually control the viewing angles (viewing areas) of the respective display areas DA1 and DA2.

For example, referring to FIG. 13A, the voltage generator 320 may supply the first driving voltage LV1 having a value of the first voltage V1 to the first display area DA1 and the second driving voltage LV2 having the value of the first voltage V1 to the second display area DA2. This is to operate the entire display area DA at the same viewing angle in the normal mode. In this case, both of the first display area DA1 and the second display area DA2 may operate in the first mode (share mode) described above with reference to FIG. 9A and FIG. 9B. Thus, a viewing area corresponding to each of the pixels PX disposed in the first display area DA1 and a viewing area corresponding to each of the pixels PX disposed in the second display area DA2 may be the first viewing area SA1 which is relatively wide. That is, the entire display area DA may display an image at a wide viewing angle.

In another example, referring to FIG. 13B, the voltage generator 320 may supply the first driving voltage LV1 having the value of the first voltage V1 to the first display area DA1 and the second driving voltage LV2 having a value of the second voltage V2 to the second display area DA2. Thus, each area of the display area DA is operated at a different viewing angle in the partial mode. In this case, the first display area DA1 may operate in the first mode (share mode) described above with reference to FIG. 9A and FIG. 9B, and the second display area DA2 may operate in the second mode (private mode) described above with reference to FIG. 10A and FIG. 10B. Thus, a viewing area corresponding to each of the pixels PX disposed in the first display area DA1 may be the first viewing area SA1 which is relatively wide. Also, a viewing area corresponding to each of the pixels PX disposed in the second display area DA2 may be the second viewing area SA2 which is relatively narrow. That is, each area of the display area DA may display an image at a different viewing angle.

As described above, the display device 1000 according to exemplary embodiments of the present disclosure individually controls a value of a driving voltage supplied to each display area DA. Thus, it is possible to independently control a viewing angle of an image displayed in each display area DA.

Meanwhile, FIG. 12, FIG. 13A and FIG. 13B illustrate that the display area DA operates as being divided into two display areas DA1 and DA2. However, this is merely an example, and the present disclosure is not limited thereto.

For example, further referring to FIG. 14, a display device 1000_2 according to an exemplary embodiment of the present disclosure includes the display area DA divided into a plurality of display areas DA1 to DA8. A voltage generator 320_1 individually controls values of driving voltages LV1 to LV8 supplied to the respective display areas DA1 to DA8. Thus, it is possible to independently control viewing angles of the respective display areas DA1 to DA8. For example, the display area DA may be divided into display areas in each pixel column. Thus, it is possible to independently control each display area.

As described above, a display device according to the present disclosure includes a liquid lens whose shape may be changed depending on a driving voltage. A viewing angle of a display image may be controlled by using the liquid lens.

Particularly, the shape of the liquid lens is not fixed, but changed depending on a value of the driving voltage. Therefore, the display device according to the present disclosure may exhibit various viewing angles by controlling the value of the driving voltage.

Also, the display device according to the present disclosure does not include separated emission layers and lenses having different shapes. However, the display device according to the present disclosure includes the liquid lens whose shape may be changed depending on the value of the driving voltage to display an image at various viewings angles. Therefore, the aperture ratio may be enhanced, and the luminance may be improved accordingly.

Further, the display device according to the present disclosure does not include a separate emission driver for separating an emission layer. However, the display device according to the present disclosure can control a viewing angle of a display image by controlling the shape of the liquid lens. Therefore, the area (size) of a gate driver may be reduced, and the size of a non-display area may be reduced accordingly.

Furthermore, the display device according to exemplary embodiments of the present disclosure individually controls a driving voltage for each display area and thus may independently control a viewing angle of an image displayed in each display area.

The exemplary embodiments of the present disclosure can also be described as follows:

According to an aspect of the present disclosure, the display device includes a display panel including a pixel. Also, the display device includes a light modulator that is disposed on the display panel and includes a lens configured to control a path of light supplied from the display panel. Further, the display device includes a controller that supplies a driving voltage to the light modulator. The shape of the lens may be changed depending on a value of the driving voltage.

The lens may be a liquid lens.

The lens includes a material having polarity.

As the value of the driving voltage increases, a surface tension of the lens decreases.

The lens may be disposed to overlap the pixel.

The light modulator may include a light blocking pattern that may be disposed on the display panel and includes a first opening; and an optical gap layer that may be disposed on the light blocking pattern.

The first opening may be disposed to overlap the pixel.

The light modulator further may include a first insulating layer that may be disposed on the optical gap layer, an electrode pattern that may be disposed under the first insulating layer and a lens layer that may be disposed on the first insulating layer and includes the lens.

The lens layer may further include a planarization layer that covers the lens.

The planarization layer may include non-polar oil having a low refractive index.

The electrode pattern may include a second opening, and
the second opening may overlap the first opening.

The second opening has a greater width than the first opening.

The light modulator may further include a second insulating layer that may be disposed on the lens layer; and a first electrode layer that may be disposed on the second insulating layer.

The light modulator may further include a second electrode layer that may be provided between the first insulating layer and the electrode pattern.

The driving voltage may be applied between the first electrode layer and the electrode pattern.

The driving voltage may be applied between the first electrode layer and the second electrode layer.

The display panel may include a base layer, the pixel that may be disposed on the base layer and an encapsulation layer that covers the pixels.

The display panel may display an image at a wide viewing angle when the driving voltage having a value of a first voltage may be supplied, and displays an image at a narrow viewing angle when the driving voltage having a value of a second voltage lower than the first voltage may be supplied.

The controller individually may control the value of the driving voltage supplied to each display area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display panel including a pixel;
a light modulator on the display panel, the light modulator including a lens that overlaps the pixel and is configured to control a path of light supplied from the pixel; and
a controller configured to supply a driving voltage to the light modulator,
wherein a shape of the lens changes according to a change in value of the driving voltage.

2. The display device according to claim 1, wherein the lens comprises liquid and
wherein a surface tension of the lens decreases as the value of the driving voltage increases.

3. The display device according to claim 1, wherein the light modulator further comprises:
an electrode pattern between the display panel and the lens, the electrode pattern having a polarity that is different from a polarity of the lens.

4. The display device according to claim 3, wherein the light modulator further comprises:
a light blocking pattern on the display panel, the light blocking pattern including a first opening that overlaps the lens and the pixel; and
an optical gap layer on the light blocking pattern, the optical gap layer between the lens and the light blocking pattern.

5. The display device according to claim 4, wherein the light modulator further comprises:
a first insulating layer on the optical gap layer, the electrode pattern between the first insulating layer and the optical gap layer;
a lens layer that is on the first insulating layer, the lens layer including the lens; and
a planarization layer that covers the lens,
wherein the planarization layer includes non-polar oil having a refractive index that is less than a refractive index of the lens.

6. The display device according to claim 4, wherein the electrode pattern includes a second opening that overlaps the first opening of the light blocking pattern and wherein the second opening has a width that is greater than a width of the first opening.

7. The display device according to claim 5, wherein the light modulator further comprises:
a second insulating layer on the lens layer;
a first electrode layer on the second insulating layer; and,
a second electrode layer between the first insulating layer and the electrode pattern,
wherein the driving voltage is applied to the first electrode layer and the electrode pattern.

8. The display device according to claim 1, wherein the display panel displays an image at a first viewing angle responsive to the driving voltage having a first value, and displays an image at a second viewing angle that is narrower than the first viewing angle responsive to the driving voltage having a second value that is less than the first value.

9. The display device according to claim 1, wherein the controller individually controls the value of the driving voltage supplied to each display area.

10. A display device comprising:
a display panel including a plurality of pixels; and
a light modulator on the display panel, the light modulator including a plurality of lenses that each overlap a corresponding one of the plurality of pixels,
wherein the display device is configured to switch between a first mode having a first viewing angle and a second mode having a second viewing angle that is different from the first viewing angle, and during the first mode a lens from the plurality of lenses has a first shape and during the second mode the lens has a second shape that is different from the first shape.

11. The display device according to claim 10, further comprising:
a controller configured to supply a first driving voltage to the light modulator during the first mode such that the lens has the first shape and supply a second driving voltage that is less than the first driving voltage to the light modulator during the second mode such that the lens has the second shape and
wherein the first viewing angle is wider than the second viewing angle.

12. The display device according to claim 11, wherein the light modulator further comprises:
a light blocking pattern on the display panel, the light blocking pattern including a plurality of first openings that each overlap a corresponding one of the plurality of pixels and a corresponding lens from the plurality of lenses;
an optical gap layer on the light blocking pattern;
an electrode pattern on the optical gap layer, the electrode pattern including a plurality of second openings that each overlap a corresponding one of the plurality of first openings; and
a first electrode layer on the plurality of lenses.

13. The display device according to claim 12, wherein the controller is configured to apply the first driving voltage or the second driving voltage to the first electrode layer and the electrode pattern.

14. The display device according to claim 12, further comprising:
a second electrode layer between the electrode pattern and the plurality of lenses,
wherein the controller is configured to apply the first driving voltage or the second driving voltage to the first electrode layer and the second electrode layer.

15. The display device according to claim 11, wherein the lens comprises liquid and a surface tension of the lens decreases to generate the first shape of the lens responsive to the controller switching from supplying the second driving voltage to the first driving voltage, and the surface tension of the lens increases to generate the second shape of the lens responsive to the controller switching from supplying the first driving voltage to the second driving voltage.

16. The display device according to claim 10, wherein the display panel comprises a first display area and a second display area, and the first display area is configured to operate in the first mode while the second display area is configured to operate in the second mode.

17. A display device comprising:
a display panel including a plurality of pixels; and
a light modulator on the display panel, the light modulator including an insulating layer and a plurality of lenses on the insulating layer, each of the plurality of lenses overlapping a corresponding one of the plurality of pixels; and
a controller configured to supply one of a first driving voltage to the light modulator and a second driving voltage to the light modulator,
wherein a first contact angle is formed between the insulating layer and a part of a lens that is in contact with the insulating layer with respect to a reference that is perpendicular to the insulating layer responsive to the first driving voltage, and a second contact angle that is different from the first contact angle is formed between the insulating layer and the part of the lens with respect to the reference responsive to the second driving voltage.

18. The display device according to claim 17, wherein the first driving voltage is greater than the second driving voltage, and the first contact angle is less than the second contact angle.

19. The display device according to claim 17, wherein the lens comprises liquid and a surface tension of the lens decreases to generate the first contact angle responsive to the controller switching from supplying the second driving voltage to the first driving voltage, and the surface tension of the lens increases to generate the second contact angle responsive to the controller switching from supplying the first driving voltage to the second driving voltage.
